(19) United States
(12) Patent Application Publication
(10) Pub. No.: US 2026/0096395 A1
(43) Pub. Date: Apr. 2, 2026

(54) CARRIER FOR DEBONDING OF BONDED STACK WITH PASSIVATION LAYER

(71) Applicant: PulseForge, Inc, Austin, TX (US)

(72) Inventors: Ian M. Rawson, Austin, TX (US); Harry Chou, Austin, TX (US); Kurt A. Schroder, Coupland, TX (US)

(21) Appl. No.: 19/348,184

(22) Filed: Oct. 2, 2025

Related U.S. Application Data
(60) Provisional application No. 63/702,433, filed on Oct. 2, 2024.

(51) Int. Cl. H01L 21/683

(52) U.S. Cl. CPC H10P 72/74

(57) ABSTRACT

A reusable carrier structure for temporarily carrying electronics structures to be debonded from the carrier structure by a debonding light during temporary bonding cycles. The reusable carrier structure includes a carrier body that is substantially transparent to at least some of the debonding light, a light-absorbing layer. The reusable carrier structure can include a passivation layer configured to protect the light-absorbing layer from degradation so the carrier structure can be used in multiple temporary bonding cycles in which the carrier structure is adhesively bonded to the reusable carrier structure. The reusable can include a protective interlayer configured to protect a carrying surface of the carrier body from degradation during bonding cycles.

### CROSS-REFERENCE TO RELATED APPLICATIONS

This application claims the benefit of U.S. Provisional Application No. 63/702,433, filed Oct. 2, 2024, which is hereby incorporated herein by reference in its entirety.

### FIELD

The present disclosure generally relates to electronics device manufacturing, and more particularly equipment and methods that involve temporarily bonding an electronics structure to a carrier for processing.

### BACKGROUND

This disclosure is directed to equipment and methods for temporary bonding and debonding (TBDB), which can be employed to affix fragile materials to a maneuverable carrier to facilitate the processing of electronics structures such as electronics devices (e.g., small-scale electronics components, such as epoxy molding compound packaging, integrated circuit packaging, power or MOS devices, multijunction or tandem solar cells, two-dimensional materials, battery materials, and, more broadly, wafers and panels) in manufacturing settings.

### SUMMARY

In one aspect, a reusable carrier structure is configured for temporarily carrying electronics structures to be debonded from the carrier structure by a debonding light in temporary bonding cycles. The reusable carrier structure comprises a carrier body. The carrier body comprises a material that is substantially transparent to light in one or more wavelengths of the debonding light. The reusable carrier structure additionally includes a light-absorbing layer supported by the carrier body. The light-absorbing layer is configured to absorb debonding light to generate heat for debonding the electronics structures from the carrier structure. The reusable carrier structure further includes a passivation layer supported by the carrier body. The carrier structure is configured to temporarily carry one or more electronics structures in multiple discrete temporary bonding cycles. The passivation layer is configured to protect the light-absorbing layer from degradation to facilitate reuse of the carrier structure in multiple temporary bonding cycles.

In another aspect, a reusable carrier structure is configured for temporarily carrying electronics structures to be debonded from the carrier structure by a debonding light in temporary bonding cycles. The reusable carrier structure comprises a carrier body comprising a material that is substantially transparent to light in one or more peak wavelengths of the debonding light. The reusable carrier structure additionally includes a light-absorbing layer that is supported by the carrier body. The light-absorbing layer is configured to absorb debonding light to generate heat for debonding the electronics structures from the carrier structure. The reusable carrier structure additionally includes a protective layer supported by the carrier body and located between the carrier body and the light-absorbing layer. The carrier structure is configured to temporarily carry one or more electronics structures in multiple discrete temporary bonding cycles. The protective layer is configured to protect a carrying surface of the carrier body from degradation when heat generated by the light-absorbing layer is transferred to the carrier body to permit reuse of the carrier structure in additional temporary bonding cycles.

Other objects and features will be in part apparent and in part pointed out hereinafter.

### BRIEF DESCRIPTION OF THE DRAWINGS

FIG. 1A is a schematic of a reusable carrier structure and an electronics structure in accordance with an example temporary bonding and debonding process;

FIG. 1B is a schematic of a bonded stack comprising the reusable carrier structure and electronics structure shown in FIG. 1A, and a temporary adhesive between the reusable carrier structure and the electronics structure, wherein the electronics structure has been subjected to backside processing;

FIG. 1C is a schematic of the bonded stack of FIG. 1B positioned beneath a light source providing a debonding light to debond the processed electronics structure from the reusable carrier structure;

FIG. 1D is a schematic of the reusable carrier structure and the processed electronics structure following debonding;

FIG. 2A is a diagram of a reusable carrier structure comprising a passivation layer in accordance with an embodiment;

FIG. 2B is a diagram of a bonded stack comprising the reusable carrier structure of FIG. 2A temporarily bonded to an electronics structure and exposed to a debonding light through the carrier;

FIG. 2C is a diagram of the reusable carrier structure and electronics structure of FIG. 2B after debonding by the debonding light;

FIG. 3 is a diagram of a reusable carrier structure comprising a passivated light-absorbing layer in accordance with another embodiment;

FIG. 4 is a diagram of a reusable carrier structure comprising a passivation layer in accordance with another embodiment;

FIG. 5 is a diagram of a reusable carrier structure comprising a passivation layer in accordance with another embodiment;

FIG. 6 is a diagram of a reusable carrier structure comprising a passivation interlayer in accordance with another embodiment;

FIG. 7 is a diagram of a reusable carrier structure comprising a chemically strengthened carrier body in accordance with another embodiment;

FIG. 8 is a diagram of a reusable carrier structure comprising a passivation interlayer and an external passivation layer in accordance with another embodiment;

FIG. 9 is a diagram of a reusable carrier structure comprising a plurality of passivation interlayers in accordance with another embodiment;

FIG. 10 is a diagram of a reusable carrier structure comprising a passivation interlayer in accordance with another embodiment; and

FIG. 11 is a diagram of a reusable carrier structure comprising a passivation interlayer in accordance with another embodiment.

Corresponding reference characters indicate corresponding parts throughout the drawings.

### DETAILED DESCRIPTION

The present disclosure relates to varieties of carriers (broadly, “carrier structures”) used in TBDB and a bonded stack that includes such a carrier that carries an electronics structure so processing operations can be performed while the electronics structure is temporarily carried by the carrier. In the TBDB process, an adhesive is typically used to temporarily secure a functional material (e.g., electronics structure) to a carrier (e.g., a rigid dummy substrate) for processing. After processing, lasers, heat, chemicals, or mechanical methods may be employed to separate the processed device from its respective carrier by damaging an interface between the temporary adhesive and the processed device or between the adhesive and the carrier. In the field of semiconductor wafer debonding, using a flashlamp (e.g., broadband or incoherent light source) as a debonding light source may be referred to as photonic debonding. A debonding process using a laser (e.g., coherent light source) as a debonding light source may be referred to as laser debonding.

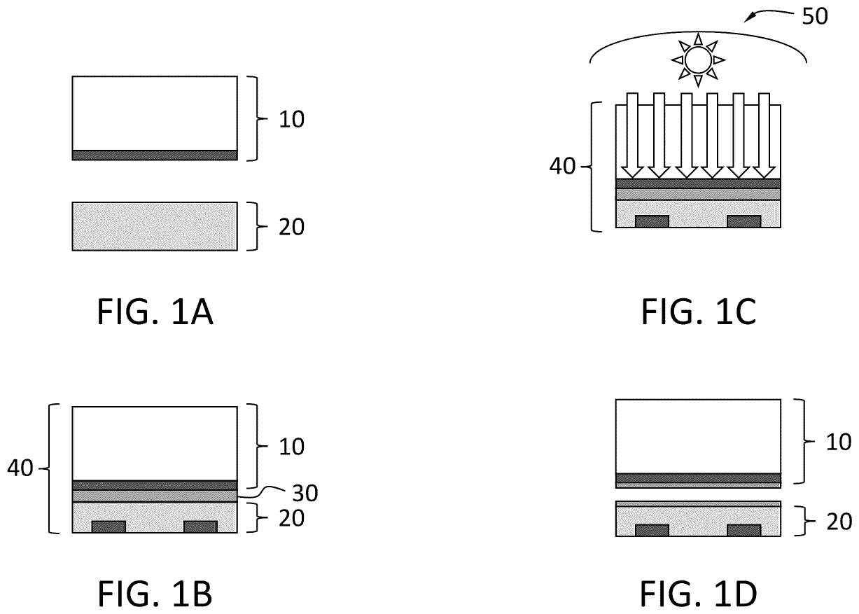

Referring to FIGS. 1A-ID, an example of a TBDB process using a reusable carrier structure and an electronics structure is shown. A reusable carrier structure suitable for TBDB using a debonding light is shown generally as reference number 10 in FIG. 1A. An electronics structure suitable for processing when carried on the reusable carrier structure 10 is shown generally as reference number 20. As will be described in greater detail in the examples provided below, the reusable carrier structure 10 can include a carrier body (e.g., a substrate made of a rigid, transparent or partially transparent material like glass or a polymer) and one or more additional layers of additional material carried by the carrier to provide various carrier functions such as light absorption, protection from physical and/or chemical wear, reduction of thermal stress, light manipulation, and other functions. Although various embodiments described herein are described as including layers having particular compositions or characteristics, it will be appreciated that the same layers or additional layers can be provided on carrier structures for additional functions without departing from the scope of the present disclosure.

As best seen in FIG. 1B, a bonded stack 40 can be formed by using a bonding layer 30 (e.g., an adhesive) to temporarily bond the carrier structure 10 to the electronics structure 20. For example, the bonding layer 30 can be cured via thermal energy (e.g., heat curing) or exposure to electromagnetic energy (e.g., UV curing) to temporarily bond the carrier structure 10 to the electronics structure 20. As can further be seen in FIG. 1B, the electronics structure 20 can be processed while bonded to the carrier structure 10 in the bonded stack 40. As non-limiting examples, the electronics structure 20 can be processed by operations such as wafer/substrate thinning, redistribution layer (RDL) buildup, deep reactive ion etching (DRIE), photolithography, sputtering, via formation, plating, device building, and other suitable operations.

Referring now to FIG. 1C, after the desired processing has been performed on the electronics structure 20 while the bonded stack 40 is fully formed, the electronics structure can be debonded from the reusable carrier structure 10 by exposing the carrier side of the bonded stack to a debonding light source 50. It will be appreciated that the reusable carrier structure 10 is configured to generate heat to weaken the bonding layer 30 by absorbing a debonding light from the debonding light source 50. As can be seen in FIG. 1D, after the bonding layer 30 is weakened, the reusable carrier structure 10 can be physically separated from the electronics structure 20. For example, the separation can be achieved using equipment as described in U.S. Pat. No. 11,996,384, the disclosure of which is hereby incorporated herein by reference in its entirety. It will be appreciated that residual portions of the weakened bonding layer 30 can remain on one or both of the reusable carrier structure 10 and the electronics structure 20 after separation. After separation, the reusable carrier structure 10 and the electronics structure 20 are preferably cleaned using mechanical and/or chemical cleaning methods to remove the residual portions of the bonding layer 30 prior to reuse of the reusable carrier structure 10 in subsequent TBDB processes and prior to subsequent electronic device manufacturing processes involving the electronics structure 20.

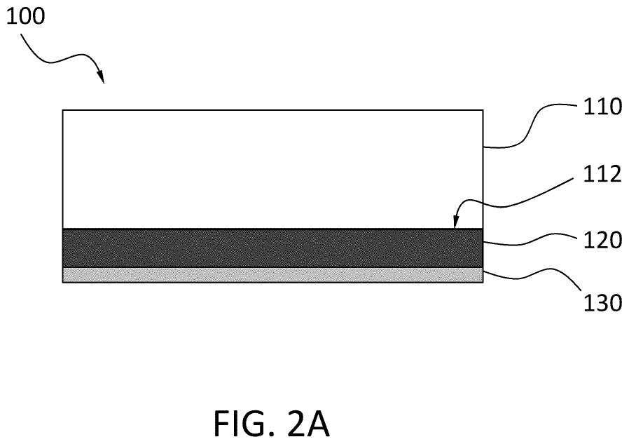

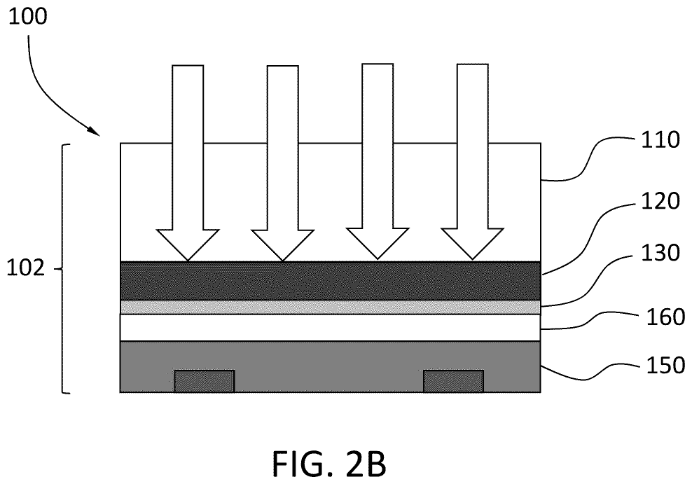

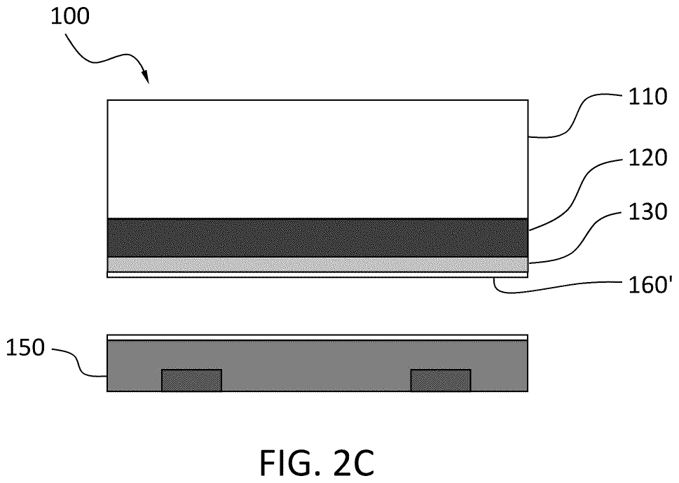

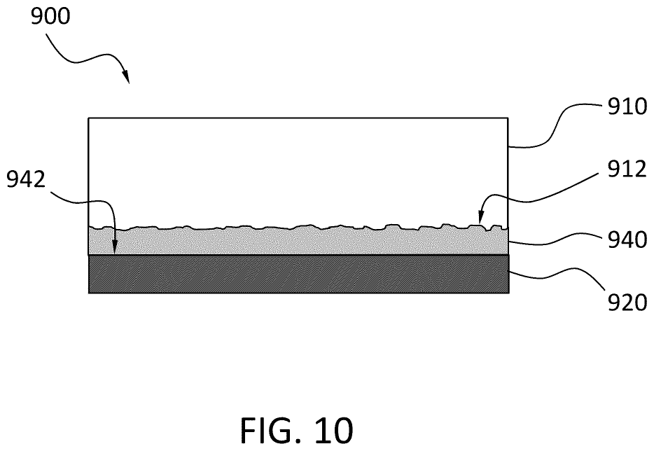

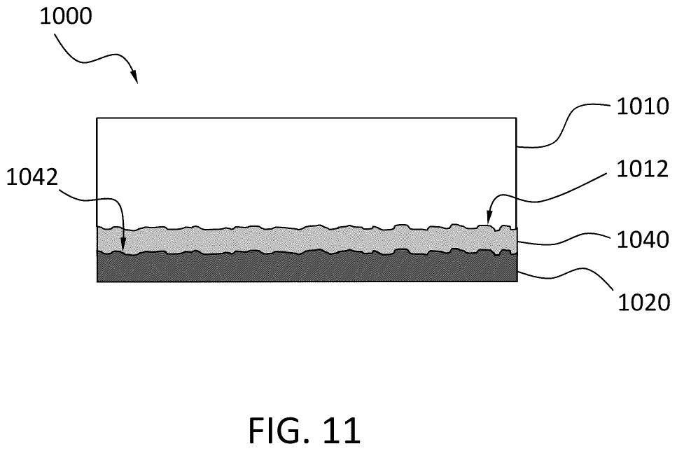

Described herein are examples of reusable carrier structures for use in TBDB processes in which the reusability of the carrier is enhanced. One example of a reusable carrier structure with a protective passivation layer is shown generally in FIG. 2A using reference number 100. The reusable carrier structure 100 includes a carrier body 110, a light-absorbing layer (LAL) 120 carried on the carrier base, and a passivation layer 130 (e.g., a protective coating) covering an outer surface of the LAL. The passivation layer 130 is located at a bonding end of the reusable carrier structure 100 (e.g., at a free end of the reusable carrier structure where a bonding layer or layers are provided to bond the reusable carrier structure to electronics structures for bonding cycles). Although the LAL 120 is carried directly on a carrier surface 112 that is defined by a first side of the carrier body 110 in the present example, it will be appreciated that additional material (e.g., interlayers) may be positioned between the carrier body and the LAL without departing from the scope of the present disclosure. It is contemplated that the carrier body 110 comprises a rigid, thermally stable material that is light-transmissive (e.g., at least 50% transmissive to light in at least a portion of the wavelengths of debonding light used for debonding the reusable carrier structure 100 from an electronics structure in accordance with the principles discussed above). As non-limiting examples, the carrier body 110 can comprise a silicon, quartz, or glass substrate (or wafer) having a thickness ranging from tens of microns (e.g., 50 microns) to hundreds of microns (e.g., 200 to 500 microns). The carrier surface 112 of the carrier body 110 is smooth, though it will be appreciated that, in alternative carrier structures, suitable carrier surfaces may have structured and/or roughened textures, as described in greater detail below in connection with FIGS. 10-11.

Referring still to FIG. 2A, the LAL 120 is supported by the carrier body 110. Referring also to FIG. 2B, the LAL is configured to absorb a sufficient amount of debonding light transmitted through the carrier body (represented by arrows) to generate debonding heat in at least a portion of a bonding layer 160 that temporarily bonds an electronics structure 150 to the reusable carrier structure 100 in a temporarily bonded stack 102. As can be seen in FIG. 2C, when sufficient heat has been generated to weaken the bonding layer 160, the carrier structure 100 can be separated from the electronics structure 150. The LAL 120 can comprise one or more of a variety of rigid, thermally stable materials. As a non-limiting example, the LAL 120 can comprise a metal (such as molybdenum or tungsten) or a metal alloy, such as an alloy comprising tungsten (majority) and titanium (minority) (e.g., approximately 90% tungsten and approximately 10% titanium (by mass)). It will be appreciated that a metal or alloy LAL 120 can be applied to the carrier body 110 by known deposition methods such as sputtering, thermal evaporation, atomic layer deposition, or vapor deposition. Further non-limiting examples of light-absorbing materials for the LAL 120 can include silicon thermally stable polymers, or other rigid, thermally stable materials that are sufficiently absorptive in the wavelength range of the debonding light to facilitate debonding as described above. The LAL 120 can be selected to provide a coefficient of thermal expansion (CTE) of the LAL that is closely matched to a CTE of the carrier body 110. For example, a CTE of the LAL 120 can be matched to within 1.5×106/K of a CTE of the carrier body 110, e.g., by using Corning Eagle XG glass as a carrier body material and a 90% tungsten, 10% titanium alloy as an LAL material. It will be appreciated that a thickness of the LAL 120 is generally determined based on the light absorption and heat transfer characteristics of the light-absorbing material, though it is contemplated the thickness of the LAL is generally between about 10 nm and about 1 micron when a metal or metal-alloy LAL is used. Other configurations can be used without departing from the scope of the present disclosure.

Referring still to FIGS. 2A-2C, the passivation layer 130 will now be described in further detail. The passivation layer 130 comprises a durable, thermally stable material that enhances the durability and longevity of the carrier structure 100 by reducing degradation of the LAL 120 during each use (e.g., during each TBDB cycle) and/or between uses when the reusable carrier structure 100 is not bonded to an electronics structure (e.g., 150) and the open faces of the carrier structure may be exposed to chemical reactants and/or physical agitants. It will be appreciated that degradation, as described herein, should be understood broadly to include, as non-limiting examples, degradation from thermal stress, degradation from physical contact, and degradation from chemical reactions. Further details and advantages of the passivation layer 130, and variations thereof, will be described below.

The passivation layer 130 can comprise a dielectric material such as a ceramic or a hardcoat material. Non-limiting examples of materials that can be used in passivation layer 130 include silicon nitride, silicon dioxide, silicon carbide, aluminum oxide, diamond-like carbon (DLC), silicon oxycarbide, hafnia, and/or boron coating materials. Additionally and/or in the alternative, the passivation layer 130 may comprise polymeric materials such as polyimide and parylene. It is contemplated that the passivation layer 130 can be applied on the LAL 120 using a variety of techniques including vacuum deposition or solution deposition methods. Non-limiting examples of contemplated deposition methods include physical vapor deposition, chemical vapor deposition, atomic layer deposition, spray coating, spin coating, thermal oxidation, plasma-assisted deposition, electrochemical deposition, sol-gel coating, inkjet printing, and screen printing. The passivation layer 130 can have a thickness ranging from about 10 nm to about 1 micron, more desirably from about 20 nm to about 800 nm, and more desirably from about 30 nm to about 600 nm. Other thicknesses may be suitable depending on the structural and thermal characteristics of the passivation material selected for the passivation layer 130. It is contemplated that the passivation layer 130 is thick enough to substantially mitigate the degradation effects described herein but is thin enough not to interfere substantially with heat transfer between the LAL 120 and the bonding layer 160 during debonding. Additionally, the passivation layer 130 desirably has a CTE that is closely matched to the CTE of the LAL 120 (e.g., within 1.5×10⁻⁶/K). Other configurations can be used without departing from the scope of the present disclosure.

Referring still to FIGS. 2A-2C, the passivation layer 130 is configured to cover substantially all of an outer (e.g., non-carrier-body-facing) surface of the LAL 120. It will be appreciated that the outer surface of the LAL 120 would be unshielded from various external stresses if the passivation layer were not present. As best seen in FIG. 2A, when the reusable carrier structure 100 is not bonded to other structures, the passivation layer 130 shields the LAL 120 from direct exposure to chemical reactants (e.g., oxygen, which can cause oxidation) and physical agitants (e.g., bumping or scraping), thereby providing passive preservation for the LAL where an exposed LAL could be exposed to damaging conditions.

As best seen in FIG. 2B, the passivation layer 130 additionally provides critical protection to the LAL 120 during active TBDB processes. For example, the passivation layer 130 is not susceptible to reactions with the bonding layer 160 or residual materials produced during curing and/or debonding processes. Moreover, the passivation layer 130 provides structural support for the LAL 120 during intense periods of thermal stress when the LAL rapidly absorbs energy from one or more intense pulses of light (such as the debonding light discussed herein) to generate heat and subsequently cools rapidly as heat is dissipated. For example, it is contemplated that the LAL can be heated from ambient temperature to around 700° C. in less than a millisecond. It will be appreciated that the structural reinforcement provided by the passivation layer 130 can be especially pronounced when the CTE of the passivation layer is closely matched to LAL 120 to alleviate stress at an interface between the passivation layer and the LAL. The presence of the passivation layer 130 can reduce surface-level thermal degradation (e.g., fracturing) in the LAL 120 that would be more likely to occur during periods of rapid thermal expansion and contraction if the LAL were not reinforced. Because the bonding layer 160 is configured to weaken upon exposure to debonding heat, an unreinforced LAL is exposed to substantially no reinforcement from the bonding layer 160 near the interface between the LAL and the bonding layer, and thus an unreinforced LAL is subject to comparatively greater thermal stress at this junction than the LAL 120 of FIG. 2B, which is reinforced by passivation layer 130.

As best seen in FIG. 2C, the passivation layer 130 additionally provides protection to the LAL 120 during mechanical or chemical cleaning processes in which residual portions 160′ of the weakened bonding layer 160 are desirably removed. Because the passivation layer 130 comprises a physically durable, chemically stable material that shields the LAL 120 from harsh environmental conditions, the LAL sustains less degradation over multiple TBDB cycles and cleaning cycles associated therewith. It is contemplated that the durability and longevity of the reusable carrier structure 100 is substantially enhanced due to the presence of the passivation layer 130 as opposed to a carrier structure with an exposed LAL. For example, it has been found that a reusable carrier structure with a Corning Eagle XG glass carrier body having a thickness of 200 microns, a 90% tungsten/10% titanium LAL having a thickness of 200 nm, and a silicon nitride passivation layer having a thickness of 50 nm can have a lifespan approximately 75% longer than a similar carrier structure without the silicon nitride passivation layer (e.g., can be used seven times before experiencing critical degradation, rather than four times when the carrier lacks a passivation layer).

In addition to the foregoing, the inclusion of a passivation layer can result in reductions in debonding energy thresholds between the carrier structure 110 and the bonding layer 160 due to relatively low surface energy density (or surface tension) characteristics found in passivation materials compared to traditional light-absorbing materials. In this respect, the addition of a passivation layer may also enhance the reusability of the carrier structure 100 by effectively reducing the amount of debonding energy (e.g., debonding light intensity) necessary to successfully debond the carrier structure from electronics structures. The energy reductions result in less thermal stress in the carrier structure (e.g., between the carrier body and the LAL and/or between the LAL and the passivation layer), further promoting durability and longevity. Additionally, the presence of a passivation layer can promote improved contact between the carrier structure and the bonding layer after repeated uses due to a general decrease in degradation on the primary surface (or surfaces) where the bonding layer contacts the carrier structure.

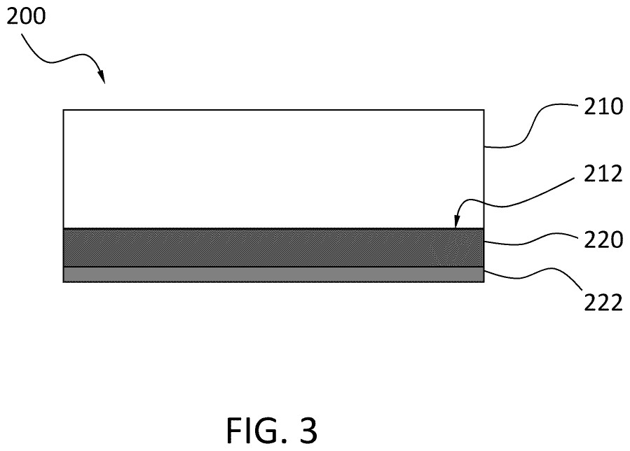

It will be appreciated that the formation and relative placement of passivation layers relative to the carrier body and the LAL can be modified in numerous ways without departing from the scope of the present disclosure, several non-limiting examples and/or combinations of which are described in the following paragraphs. For example, an alternative example of a reusable carrier structure with a light-absorbing layer and a protective passivation layer is shown generally in FIG. 3 using reference number 200. The reusable carrier structure 200 comprises a carrier body 210 with a carrier surface 212 and an LAL 220 that covers the carrier surface 212. In this example, the LAL 220 comprises a metal or metal alloy, and a passivation layer 222 is formed by passivating an outer portion of the LAL (e.g., exposing to a passivating reaction like oxidation or acid cleaning). Accordingly, it will be appreciated that a passivation layer may be integrally formed with the LAL without departing from the scope of the present disclosure. An example of a metal alloy for natural passivation comprises a combination of chromium (e.g., about 15% by weight) (broadly, third alloy component), titanium (e.g., minority, such as about 2% by weight) (broadly, second alloy component), and tungsten (e.g., majority, such as about 83% by weight) (broadly, first alloy component). When the outer boundaries of the LAL are exposed to environmental oxygen (e.g., air), the chromium in the alloy undergoes oxidation and provides for a robust chromium oxide conformal layer that protects the portions of the LAL that are not oxidized. The combination of the chromium oxide layer and the additional titanium significantly reduces a susceptibility of the tungsten to high-temperature oxidation and degradation. It will be appreciated that nickel can be used as a substitute or additive for a similar self-passivating effect as chromium. Other configurations can be used without departing from the scope of the present disclosure. For example, in the example alloy given, nickel can be substituted for chromium or can be used with chromium. Moreover, one or more alloy components (e.g., titanium) can be omitted.

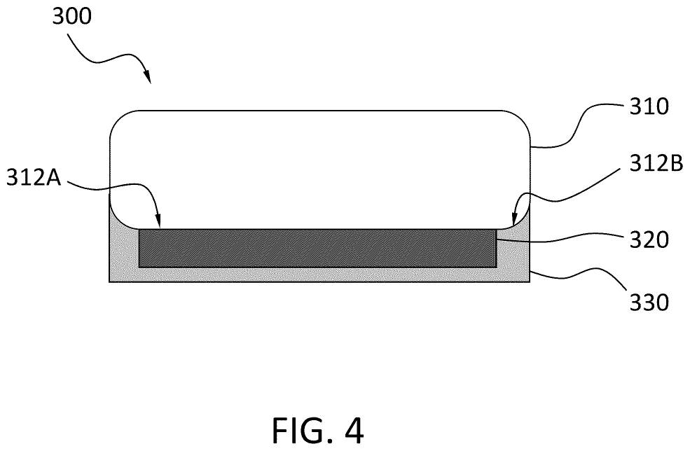

Another alternative example of a reusable carrier structure with a protective passivation layer is shown generally in FIG. 4 using reference number 300. The reusable carrier structure 300 comprises a carrier body 310 defining a working surface 312A, located inboard of the outer edges of the carrier body, and a peripheral surface 312B, located between the working surface and the outer edges of the carrier body. In this example, an LAL 320 is selectively deposited on working surface 312A and not on the peripheral surface 312B. A passivation layer 330 is deposited on the LAL 320 and the peripheral surface 312B to surround the LAL. It will be appreciated that the surrounding configuration of the passivation layer 330 promotes further protection from degradation near the outer edges of the carrier body with a relatively small impact on an overall working area of the carrier structure 300. It is contemplated that the dimensions of the peripheral surface 312B are relatively small compared to a diameter of the carrier structure 300. For example, it is contemplated that the carrier structure and LAL are generally dimensioned to carry electronics structures (e.g., wafers) having a primary dimension (e.g., a diameter) of 300 mm or greater, while a primary dimension of the peripheral surface 300 (e.g., a surface width relative to the outer edges of the carrier body 310) can be on the order of microns.

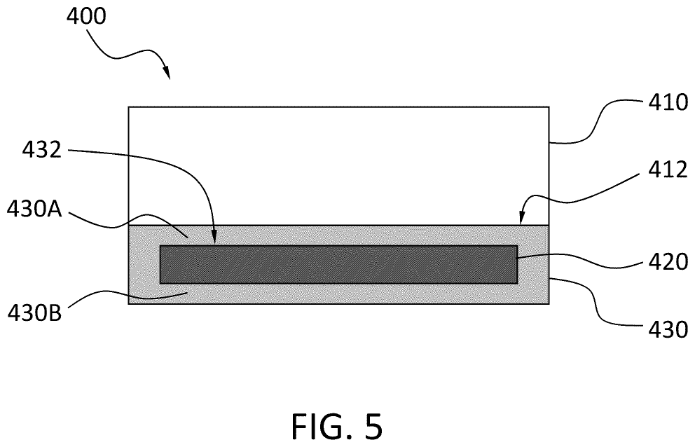

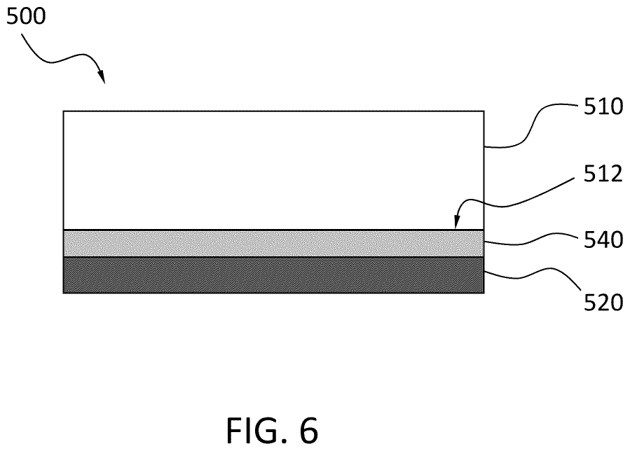

Another alternative example of a reusable carrier structure with a protective passivation layer is shown generally in FIG. 5 using reference number 400. The reusable carrier structure 400 comprises a carrier body 410 defining a carrier surface 412. A passivation layer 430 is located on the carrier surface 412 and surrounds an LAL 420. It will be appreciated that the passivation layer 430 and the LAL 420 may be deposited sequentially, e.g., by: (1) depositing a first passivation sub-layer 430A defining a support surface 432; (2) depositing the LAL on the support surface; and (3) depositing a second passivation sub-layer 430B to surround the LAL. In this manner, the passivation layer 430 surrounds the light-absorbing layer 420 on a contact side of the LAL that faces away from the carrier body 410, a carrier side of the LAL facing the carrier surface 420 (broadly, a second side), and the side surfaces extending between the contact side and the carrier side of the LAL. Moreover, it will be appreciated that the passivation layer 430 preferably comprises material that is substantially light-transmissive to debonding light so that the debonding light can be absorbed in the LAL 420 without substantial energy losses in the first passivation sub-layer 430A. The presence of first sub-layer 430A adjacent the carrier body 410 can provide further enhancements to the durability and longevity of the carrier structure 400 by reinforcing and alleviating thermal stress in portions of the carrier body near the carrier surface 412 in addition to the benefits of shielding and reinforcing the LAL 420 discussed above in connection with FIGS. 2A-2C. It will be appreciated the first sub-layer 430A is structurally and functionally similar to the passivation interlayers discussed below in the examples associated with FIGS. 6-11.

In another example, a reusable carrier structure with a protective interlayer is shown generally in FIG. 6 using reference number 500. The reusable carrier structure 500 comprises a carrier body 510 defining a carrier surface 512, a protective interlayer 540 located on the carrier surface 512, and an LAL 520 located on the protective interlayer opposite the carrier body. In this configuration, the protective interlayer 540 comprises a material that is substantially light-transmissive to debonding light so that the debonding light can be absorbed in the LAL 520 without substantial energy losses in the protective interlayer 540. The protective interlayer 540 and LAL 520 are configured to remain with the reusable carrier structure 500 for multiple TBDB processes. The protective interlayer 540 comprises a durable and thermally resistant material, such as ceramics and/or hardcoat materials like those used in the passivation layers described above. The placement of the protective interlayer 540 on the carrier surface 512 provides structural reinforcement in portions of the carrier body 510 near the carrier surface. For example, it will be appreciated that a substantial amount of heat generated in the LAL 520 from absorbing debonding light is transferred into the carrier body 510, resulting in rapid thermal expansion and contraction in this area. The protective interlayer 540 provides structural reinforcement that reduces the effects of thermal shock and corresponding degradation of the carrier body 510 near the carrier surface 512. The protective interlayer 540 preferably comprises a material that is substantially light-transmissive to debonding light so that the debonding light can be absorbed in the LAL 520 without substantial energy losses in the protective interlayer. It is contemplated that the protective interlayer 540 has a thickness conducive to providing structural reinforcement to the carrier structure 500 without substantially inhibiting transmission of light toward the LAL 520 or heat transfer between the LAL 520 and the carrier body 510 during bonding cycles. In some examples, the protective interlayer 540 can have a thickness between about 30 nm and about 600 nm.

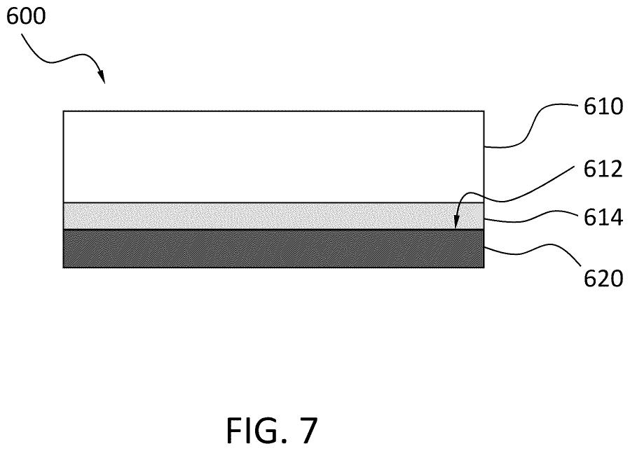

Another alternative example of a reusable carrier structure with a protective interlayer is shown generally in FIG. 7 using reference number 600. The reusable carrier structure 600 comprises a carrier body 610 defining a carrier surface 612 and comprising a chemically strengthened sub-layer 614 (broadly, a protective interlayer) located near the carrier surface, and an LAL 620 located on the chemically strengthened sub-layer. In this example, the carrier body 610 comprises a material that can be chemically strengthened through ion exchange processes, salt baths, or the like to form the chemically strengthened sub-layer 614 as an alternative to a discrete protective interlayer as described above in connection with reference number 540 in FIG. 6. Accordingly, it will be appreciated that a protective interlayer may be integrally formed with the carrier body without departing from the scope of the present disclosure.

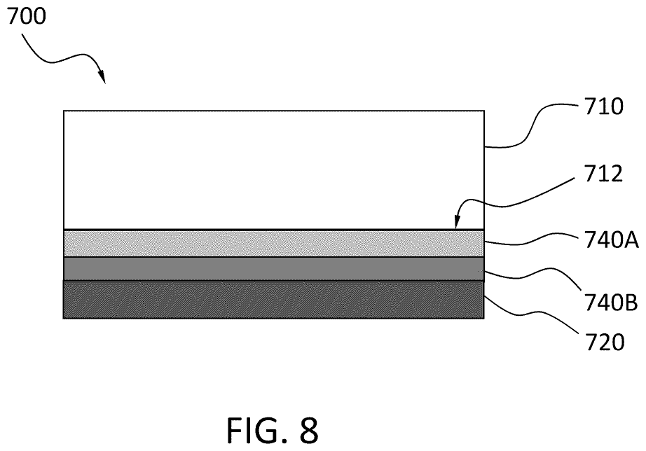

A further example of a reusable carrier with multiple protective interlayers is shown generally in FIG. 8 using reference number 700. The reusable carrier structure 700 comprises a carrier body 710 defining a carrier surface 712. A first protective sub-layer 740A is located on the carrier surface 712, and a second protective sub-layer 740B is located adjacent the first protective sub-layer opposite the carrier body 710. An LAL 720 is located adjacent the second protective sub-layer 740B opposite the first protective sub-layer 740A. It is contemplated that the first protective sub-layer 740A and the second protective sub-layer 740B comprise different materials. For example, the first protective sub-layer 740A may be selected to provide structural support at the carrier surface 712, and the second protective sub-layer 740B may be selected for optimal contact with the LAL 720 and/or to provide a CTE that is between respective CTEs of the first protective sub-layer and the LAL. It will be appreciated that the first and second protective sub-layers 740A, 740B preferably comprise materials that are substantially light-transmissive to debonding light so that the debonding light can be absorbed in the LAL 720 without substantial energy losses in either of the protective sub-layers.

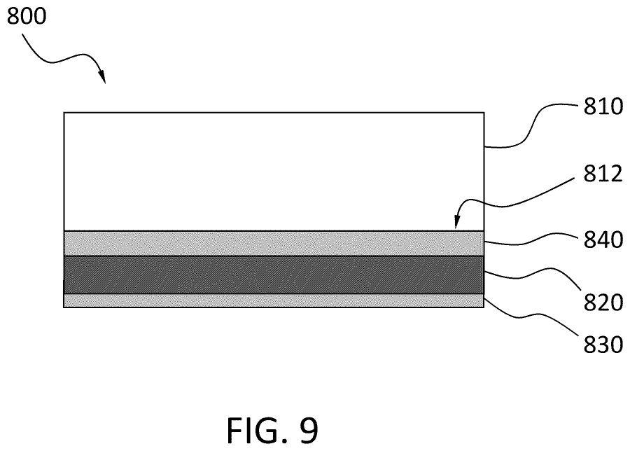

An example of a reusable carrier structure with protective layers in multiple locations is shown generally in FIG. 9 using reference number 800. The reusable carrier structure 800 comprises a carrier body 810 defining a carrier surface 812, a protective interlayer 840 located on the carrier surface 812, an LAL 820 located on the protective interlayer opposite the carrier body, and an outer passivation layer 830 located on the LAL opposite the interlayer. It will be appreciated that the reusable carrier structure generally incorporates the structural and functional features of the examples discussed above in connection with reference number 100 in FIGS. 2A-2C and reference number 500 in FIG. 6 and is configured to enhance the longevity and durability of both the carrier body 810 and the LAL 820. At least the protective interlayer 840 preferably comprises a material that is substantially light-transmissive to debonding light so that the debonding light can be absorbed in the LAL 820 without substantial energy losses in the protective interlayer.

In some instances, roughened or structured surfaces can be added to the features of a carrier structure for various reasons, such as the light manipulation effects as described in U.S. patent application Ser. No. 19/210,818, whose contents are hereby incorporated herein by reference in their entirety. Because the roughened surfaces can be susceptible to degradation (e.g., degradation from thermal stress) during TBDB cycles, protective interlayers can be located adjacent the roughened surfaces to provide targeted durability and longevity in the carrier structures without substantially detracting from the thermal performance of the carrier structures. An example of a reusable carrier structure with a roughened carrier body surface and a protective interlayer is shown generally in FIG. 10 using reference number 900. The reusable carrier structure 900 comprises a carrier body 910 defining a carrier surface 912. The carrier surface 912 can have an average surface roughness Ra of between 50 nm and 5 microns. For example, the average surface roughness Ra can be around 500 nm, which is generally on an order of magnitude of debonding light (e.g., a peak debonding light wavelength of a flashlamp that generates light in at least the visible light spectrum). It will be appreciated that the surface roughening can be achieved in a variety of ways without departing from the scope of the present disclosure. For example, the surface roughening can be achieved mechanically, such as by abrasion or lapping, or chemically, such as by chemical etching. The reusable carrier structure 900 further comprises a protective interlayer 940 located on the carrier surface 912 and an LAL 920 located on the protective interlayer opposite the carrier body 910. The protective interlayer 940 generally conforms to the shape of the roughened carrier surface 912 on the side facing the carrier body 910, and the protective interlayer is substantially smooth (e.g. has an average surface roughness Ra of less than around 10 nm) along a contact surface 942 facing the LAL.

The protective interlayer 940 is configured to provide targeted structural reinforcement to the roughened portions of the carrier body 910 along the carrier surface 912. The protective interlayer 940 can be selected to comprise a material with a CTE that closely matches the CTE of a material of the carrier body 910 (e.g., within 1.5×10⁻⁶/K) so that the rapid transfer of heat associated with heat dissipation during debonding light cycles (e.g., when pulses of debonding light are absorbed by the debonding light and heat is transferred into other portions of the reusable carrier structure 900) does not result in substantial stress along the carrier surface 912. As a non-limiting example, the protective interlayer 940 can comprise a ceramic like silicon nitride deposited on a Corning Eagle XG glass carrier body 910. The relative rigidity of the protective interlayer 940 alleviates thermal stress in the roughened portions of carrier body 910 around the carrier surface 912 and limits thermal degradation that could impair the effectiveness of the reusable carrier structure 900 after one or more uses. The contact surface 942 is substantially smooth, which can facilitate stability between the LAL 920 and the protective interlayer 940 when no roughening is desired at contact surface 942, e.g., for further light manipulation to facilitate absorption in the LAL.

Another example of a reusable carrier structure with a roughened carrier body surface and a protective interlayer is shown generally in FIG. 11 using reference number 1000. The reusable carrier structure 1000 comprises a carrier body 1010 defining a roughened carrier surface 1012, a protective interlayer 1040 located on the roughened carrier surface 1012 and defining a roughened contact surface 1042, and an LAL 1020 located on the roughened contact surface 1042. It is contemplated that the protective interlayer 1040 can be deposited on the roughened carrier surface 1012 in a manner that results in a substantially uniform thickness in the protective interlayer such that an average roughness Ra of the roughened contact surface 1042 is naturally approximately the same as the average roughness Ra of the roughened carrier surface 1012. In the alternative, active roughening operations (e.g., mechanical or chemical etching) can be performed to control the average roughness Ra of the roughened contact surface 1042 to achieve various technical objectives. It will be appreciated that the selection of a suitable, physically and thermally stable material with substantial light transmissivity in the debonding light wavelength range (e.g., a ceramic, a hardcoat material, and/or other passivation materials as described herein) promotes stability at the contact interface between the protective interlayer 1040 and the LAL 1020, which can mitigate degradation in the LAL in a similar manner to reductions in degradation that could occur in the carrier body 1010, as was described above in connection with the reusable carrier structure 900 in FIG. 10.

When introducing elements of the present disclosure or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the present disclosure are achieved and other advantageous results attained.

As various changes could be made in the above constructions and methods without departing from the scope of the present disclosure, it is intended that all matter contained in the above description and shown in the accompanying drawings shall be interpreted as illustrative and not in a limiting sense. Although several examples of reusable carrier structures and features thereof are described above in connection with certain embodiments, it will be appreciated that numerous additions, combinations, and other modifications to the features described herein can be carried out without departing from the scope of the present disclosure.

### Other Statements of the Disclosure

The following are statements or features of invention described in the present disclosure. Some or all of the following statements may not be currently presented as claims. Nevertheless, the statements are believed to be patentable and may subsequently be presented as claims. Associated methods corresponding to the statements or apparatuses below, and products and apparatuses corresponding to the methods below, are also believed to be patentable and may subsequently be presented as claims. It is understood that the following statements may refer to and be supported by one, more than one, or all the embodiments described above.

A1. A method of producing an electronics structure carrier for temporarily carrying an electronics structure to be debonded from the electronics structure carrier, the method comprising:
providing a carrier body comprising a material that is substantially transparent to light in one or more wavelengths of the debonding light;
   providing a light-absorbing layer supported by the carrier body and configured to absorb debonding light to generate heat for debonding the electronics structures from the carrier structure; and
   forming a passivation layer supported by the carrier body; the passivation layer being configured to protect the light-absorbing layer from degradation to facilitate reuse of the carrier structure in multiple temporary bonding cycles.

B1. A reusable carrier structure for temporarily carrying electronics structures to be debonded from the carrier structure by a debonding light in temporary bonding cycles, the reusable carrier structure comprising:
a carrier body comprising a material that is substantially transparent to light in one or more wavelengths of the debonding light;
a light-absorbing layer supported by the carrier body and configured to absorb debonding light to generate heat for debonding the electronics structures from the carrier structure; and
a passivation layer supported by the carrier body;
wherein the carrier structure is configured to temporarily carry one or more electronics structures in multiple temporary bonding cycles; and
wherein the passivation layer is configured to protect the light-absorbing layer from degradation to facilitate reuse of the carrier structure in multiple temporary bonding cycles.

B2. A method of using the reusable carrier structure of statement B1 to temporarily carry an electronics structure for processing, the method comprising:
forming a temporary stack comprising the reusable carrier structure, a first electronics structure to be processed, and a temporary adhesive;
processing the first electronics structure while the first electronics structure is temporarily bonded to the carrier structure;
heating an area of the bonded stack to cause at least a portion of the temporary adhesive to weaken adhesively; and
separating the processed first electronics structure from the carrier structure.

What is claimed is:

1. A reusable carrier structure for temporarily carrying electronics structures to be debonded from the carrier structure by a debonding light in temporary bonding cycles, the reusable carrier structure comprising:
a carrier body comprising a material that is substantially transparent to light in one or more wavelengths of the debonding light;
a light-absorbing layer supported by the carrier body and configured to absorb debonding light to generate heat for debonding the electronics structures from the carrier structure; and
a passivation layer supported by the carrier body;
wherein the carrier structure is configured to temporarily carry one or more electronics structures in multiple temporary bonding cycles; and
wherein the passivation layer is configured to protect the light-absorbing layer from degradation to facilitate reuse of the carrier structure in multiple temporary bonding cycles.

2. The reusable carrier structure of claim 1, wherein the passivation layer is formed by passivation of a layer of material of the light-absorbing layer.

3. The reusable carrier structure of claim 1, wherein the passivation layer comprises a ceramic.

4. The reusable carrier structure of claim 1, wherein the passivation layer comprises a hardcoat material.

5. The reusable carrier structure of claim 1, wherein the light-absorbing layer has a thickness of between about 10 nm to about 1 μm, and wherein the passivation layer has a thickness of between about 30 nm and about 600 nm.

6. The reusable carrier structure of claim 1, wherein the carrier body comprises a carrier surface configured to carry the light-absorbing layer, the passivation layer, and at least one of the carrier structures; wherein the light-absorbing layer is located on the carrier surface; and wherein the passivation layer contacts the light-absorbing layer on a contact side of the light-absorbing layer facing generally away from the carrier body.

7. The reusable carrier structure of claim 6, wherein the passivation layer surrounds the light-absorbing layer on the contact side and on a second side of the light-absorbing layer other than the contact side.

8. The reusable carrier structure of claim 1, wherein the light-absorbing layer comprises a material comprising a metal or a metal alloy.

9. The reusable carrier structure of claim 8, wherein the passivation layer comprises a passivated portion of the material comprising a metal or a metal alloy.

10. The reusable carrier structure of claim 9, wherein the light-absorbing layer comprises a metal alloy that includes tungsten, titanium, and at least one of chromium or nickel.

11. The reusable carrier structure of claim 10, wherein the light-absorbing layer comprises a metal alloy comprising about 83% tungsten, about 15% chromium, and about 2% chromium.

12. The reusable carrier structure of claim 8, wherein the light-absorbing layer comprises an alloy that includes tungsten and titanium.

13. The reusable carrier structure of claim 1, wherein the light-absorbing layer and the passivation layer each comprise material having a CTE within 1.5×10⁻⁶/K of a CTE of the carrier body.

14. The reusable carrier structure of claim 1, wherein at least a portion of the passivation layer is located between the carrier body and the light-absorbing layer.

15. The reusable carrier structure of claim 1, further comprising a protective interlayer located between the carrier body and the light-absorbing layer; wherein the protective interlayer comprises a material that is substantially transparent to light in one or more peak wavelengths of the debonding light and that has a CTE within 1.5×10⁻⁶/K of a CTE of the carrier body.

16. A system comprising a flashlamp and a bonded stack comprising the reusable carrier structure of claim 1 and an electronics structure temporarily bonded to the reusable carrier structure; wherein the flashlamp is configured to provide the debonding light.

17. The system of claim 16, wherein the flashlamp is configured to emit pulses of debonding light having peak wavelengths in the NIR-visible-UV spectrum.

18. The reusable carrier structure of claim 1, wherein the passivation layer is configured to protect the reusable carrier structure from chemical degradation.

19. The reusable carrier structure of claim 1, wherein the passivation layer is configured to protect the reusable carrier structure from physical degradation.

20. The reusable carrier structure of claim 1, wherein the passivation layer is configured to protect the reusable carrier structure from thermal stress degradation.

21. The reusable carrier structure of claim 1, wherein the passivation layer is located at a free end of the reusable carrier structure opposite the carrier body.

22. A method of using the reusable carrier structure of claim 1 to temporarily carry an electronics structure for processing, the method comprising:
forming a first temporary stack comprising the reusable carrier structure, a first electronics structure to be processed, and a temporary adhesive temporarily bonding the first electronics structure to the reusable carrier;
processing the first electronics structure while the first electronics structure is temporarily bonded to the reusable carrier structure;
heating an area of the first temporary stack to cause weaking of the bonding of the first electronics structure to the reusable carrier structure; and
separating the processed first electronics structure from the reusable carrier structure.

23. The method of claim 22 further comprising, after separating the processed first electronics structure from the reusable carrier structure:
forming a second temporary stack comprising the reusable carrier structure, a second electronics structure to be processed, and a temporary adhesive temporarily bonding the second electronics structure to the reusable carrier;
processing the second electronics structure while the second electronics structure is temporarily bonded to the reusable carrier structure;
heating an area of the second temporary stack to cause weaking of the bonding of the second electronics structure to the reusable carrier structure; and
separating the processed second electronics structure from the reusable carrier structure.

24. A reusable carrier structure for temporarily carrying electronics structures to be debonded from the carrier structure by a debonding light in temporary bonding cycles, the reusable carrier structure comprising:
a carrier body comprising a material that is substantially transparent to light in one or more peak wavelengths of the debonding light;
a light-absorbing layer supported by the carrier body and configured to absorb debonding light to generate heat for debonding the electronics structures from the carrier structure; and
a protective layer supported by the carrier body and located between the carrier body and the light-absorbing layer;
wherein the carrier structure is configured to temporarily carry one or more electronics structures in multiple temporary bonding cycles; and
wherein the protective layer is configured to protect a carrying surface of the carrier body from degradation when heat generated by the light-absorbing layer is transferred to the carrier body to permit reuse of the carrier structure in additional temporary bonding cycles.

25. The reusable carrier structure of claim 24, further comprising a passivation layer supported by the carrier body, wherein the passivation layer is configured to protect the light-absorbing layer from degradation to facilitate reuse of the carrier structure in multiple temporary bonding cycles.

26. The reusable carrier structure of claim 24, wherein the carrier body comprises a carrier surface having an average surface roughness Ra between around 50 nm and around 5 μm, and wherein the protective layer contacts the carrier surface.

27. The reusable carrier structure of claim 24, wherein the protective layer is configured to protect a carrying surface of the carrier body from thermal stress degradation.
